(19) United States
(12) Patent Application Publication
(10) Pub. No.: US 2024/0272231 A1
(43) Pub. Date: Aug. 15, 2024

(54) BATTERY CAPACITY MEASUREMENT

(71) Applicant: STMicroelectronics (Alps) SAS, Grenoble (FR)

(72) Inventor: Daniel Ladret, Lans en Vercors (FR)

(21) Appl. No.: 18/437,475

(22) Filed: Feb. 9, 2024

(30) Foreign Application Priority Data
Feb. 10, 2023 (FR) 2301285

(51) Int. Cl. G01R 31/388; G01R 31/378; G01R 31/389

(52) U.S. Cl. CPC G01R 31/388; G01R 31/378; G01R 31/389

(57) ABSTRACT

In one embodiment, a method can be used for measuring an effective capacity of a battery. A first measurement is performed during a phenomenon of relaxation of the battery. The first measurement measures a first voltage delivered by the in-use battery from a duration. The duration is the difference between a first initial time and a second time that is defined as the time when a first line reaches a second voltage delivered by the battery when the battery is relaxed, the first line being tangent to the origin of a curve corresponding to the evolution over time of a voltage delivered by the battery during the phenomenon of relaxation.

### CROSS-REFERENCE TO RELATED APPLICATIONS

This application claims the priority benefit of French patent application number FR2301285, filed on Feb. 10, 2023, which is hereby incorporated by reference to the maximum extent allowable by law.

### TECHNICAL FIELD

The present disclosure generally relates to the battery capacity measurement.

### BACKGROUND

The accumulator batteries, usually called batteries, are widely used to power supply numerous kinds of electronic devices.

Among the different existing types of battery, the Lithium batteries are very used to power supply small mobile electronic items such as mobile phones, connected objects, electronic cigarettes, etc. The Lithium Ferro-Phosphate batteries and the Lithium-Cobalt-Oxide batteries are example lithium batteries.

A battery is characterised by different values, including its capacity indicating the quantity of current a battery can deliver over time, and its aging indicating its degree of degradation.

It would be desirable to be able to improve, at least in part, at least some aspects of the methods of battery capacity and aging measurement.

### SUMMARY

The present disclosure generally relates to the accumulator batteries, usually called batteries and, in particular embodiments, to Lithium Ferro-Phosphate-type batteries. Particularly embodiments relate to methods of measurement of the effective capacity and the aging of such a battery.

Embodiments provide a method of battery capacity measurement easier to use and consuming less energy.

Embodiments address all or some of the drawbacks of the known methods of battery capacity measurement.

Embodiments provide a method of battery capacity measurement easier to use. One embodiment provides a method of battery capacity measurement consuming less energy.

Embodiments provide a method of battery aging measurement easier to use.

Embodiments provide a method of battery aging measurement consuming less energy.

Embodiments address all or some of the drawbacks of the known methods of battery aging measurement.

One embodiment provides a method of measurement of the effective capacity of a battery comprising a first measurement, during a phenomenon of relaxation of the battery, of a first voltage delivered by the in-use battery from a duration. The duration is the difference between a first initial time and a second time defined as the time when a first line, tangent to the origin of a curve corresponding to the evolution over time of a voltage delivered by the battery during the phenomenon of relaxation, reaches a second voltage delivered by the battery when it is relaxed.

According to an embodiment, the phenomenon of relaxation of the battery is obtained by performing a partial charge of the battery until the battery requires an end-of-charge current, the phenomenon of relaxation appearing when the partial charge is interrupted.

According to an embodiment, the value of the end-of-charge current is defined as equal to the typical capacity of the battery divided by 10 hours.

According to an embodiment, the partial charge is performed at constant current and at constant voltage.

According to an embodiment, the effective capacity is given by the following mathematical formula:

$$Ceff = Ctyp - R ( Vr - V ( t r ) )$$

where:
   Ceff is the effective capacity;
   Ctyp represents the typical capacity of the battery;
   R represents the resistance of the battery;
   Vr represents the voltage delivered by the battery when the battery is relaxed; and
   V(tr) represents the first voltage.

According to an embodiment, the method further comprises a second measurement of the resistance of the battery.

According to an embodiment, the second measurement is implemented by performing a second discharge of the battery with a first current.

According to an embodiment, the first current is higher than 500 mA.

According to an embodiment, the first discharge is the second discharge.

According to an embodiment, the battery is a battery of the Lithium Ferro-Phosphate type.

Another embodiment provides a method of measurement of the aging of a battery comprising the method previously described.

According to an embodiment, the aging of a battery is defined as the ratio of the effective capacity of the battery to the typical capacity of the battery.

Another embodiment provides an electronic cigarette adapted to implement the capacity measurement method previously described.

Another embodiment provides an electronic cigarette adapted to implement the aging measurement method previously described.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 very schematically illustrates a battery of the Lithium Ferro-Phosphate type;

FIG. 2 illustrates a block diagram illustrating an implementation mode of a method of measurement of the effective capacity of a battery and an implementation mode of a method of measurement of the aging of a battery;

FIG. 3 illustrates a curve illustrating the embodiment of a step of the methods of FIG. 2;

FIG. 4 illustrates curves illustrating the embodiment of another step of the methods of FIG. 2; and

FIG. 5 illustrates a practical example of use of the battery of FIG. 1.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

The hereinafter-described embodiments relate to the determination of the capacity of a lithium battery, and more particularly a battery of the lithium Ferro-Phosphate type, or battery of the lithium-iron-phosphate type, or battery of lithium ferrophosphate type, and of the aging of such a battery. The embodiments more particularly relate to two methods of measurement of the capacity and of the aging of a battery having a greater ease of implementation and consuming less energy.

In the following disclosure, the capacity of a battery is defined as a value, expressed in Ampere-hour (A/h), indicating the quantity of current that a battery can supply over time. The capacity of a battery degrades over time, and the causes of this degradation are for example the time itself, the use of the battery, the storage conditions of the battery as temperature and/or moisture, etc.

In the following, typical capacity is the capacity presented by a battery at the end of its manufacturing. Lastly, effective capacity, current capacity, or actual capacity of a battery is the capacity presented by a battery at a given time. The effective capacity of a battery is not greater than the typical capacity of this same battery.

In addition, in the following disclosure, the aging of a battery, or state of health of a battery, is defined by the ratio of the effective capacity to the typical capacity of this battery. The aging may be expressed as percent. Aging allows a degree of degradation of a battery to be evaluated.

FIG. 1 very schematically illustrates a lithium battery of Lithium Ferro-Phosphate type 100.

The battery 100 comprises the structure of a usual battery of Lithium Ferro-Phosphate type. The battery 100 comprises two compartments 101 (LiFePO4) and 102 (C) separated by a porous membrane 103.

The compartment 101 is filled with a crystal structure of lithium iron-phosphate allowing lithium atoms to be inserted and removed. The compartment 101 is passed through by a metal electrode 104, for example made of aluminium, forming the positive electrode, or cathode, of the battery 100. The electrode 104 directly contacts the lithium iron-phosphate structure. The electrode 104 is further coupled with a connecting terminal 105 forming the cathode terminal of the battery 100.

The compartment 102 is filled with a crystal structure of carbon, for example, graphite, allowing lithium atoms to be inserted and removed. The compartment 102 is passed through by a metal electrode 106, for example made of copper, forming the negative electrode, or anode, of the battery 100. The electrode 106 directly contacts the carbon structure. The electrode 106 is further coupled with a connecting terminal 107 forming the anode terminal of the battery 100.

The porous membrane 103 is adapted to let only the lithium atoms passing through. According to an example, the membrane 103 is made of polymer.

During the charging of the battery 100, the lithium atoms present in the compartment 101 migrate towards the compartment 102, i.e., migrate from the cathode to the anode.

During the discharge of the battery 100, the lithium atoms present in the compartment 102 migrate towards the compartment 101, i.e., migrate from the anode to the cathode.

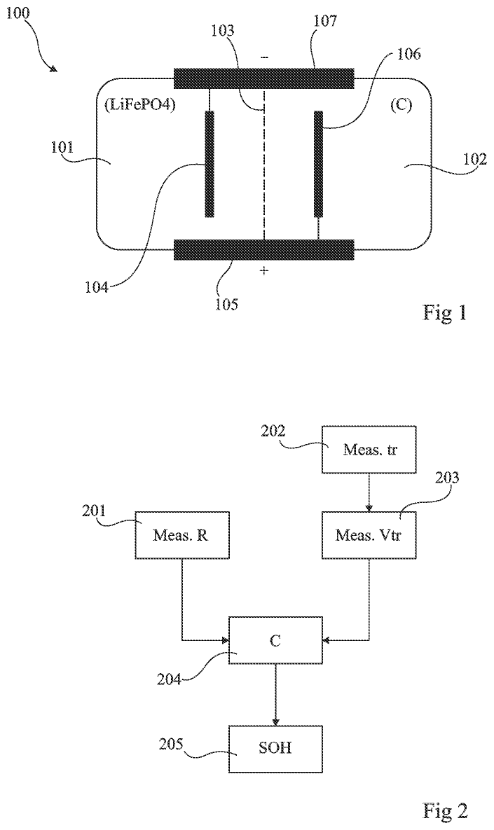

FIG. 2 is a block diagram illustrating an implementation mode of a method of measurement of the effective capacity of a battery of the type of the battery 100 described in relation with FIG. 1, and an implementation mode of a method of measurement of the aging of such a battery.

According to an embodiment, the effective capacity Ceff of a battery is given by the following mathematical formula:

$$Ceff = Ctyp - R ( Vr - V ( t r ) ) \qquad Equation 1$$

where:
Ctyp represents the typical capacity of the battery;
R represents the resistance of the battery;
Vr represents the voltage delivered by the battery when it is relaxed; and
V(tr) represents the voltage delivered by the in-use battery as hereafter defined.

According to an embodiment, the aging SOH of this same battery is given by the following mathematical formula:

$$SOH = \frac{Ceff}{Ctyp} . \qquad Equation 2$$

In order to calculate the effective capacity Ceff and the aging of the battery, it is necessary to make available the typical capacity of the battery, it is generally a data present in the data sheet of the battery, it is thus considered here as being known.

In addition, it is necessary to make available the value of the voltage Vr representative of the voltage delivered by the battery when it is relaxed. A battery of the Lithium Ferro-Phosphate type presents, as other batteries, a phenomenon of relaxation occurring after applying a current across the terminals of the battery, for example in order to charge it. More particularly, when a current was sent to the battery, the output voltage of the battery changes during a non-zero duration, called relaxation time, before stabilising. Once the output voltage stable, the battery is the relaxed. The value of the voltage delivered by the battery when it is relaxed is generally a data present in the data sheet of the battery, it is thus considered as being here known. According to another example, a measurement of this relaxation voltage can be performed as hereafter described.

More particularly, a battery of the Lithium Ferro-Phosphate type, as the battery 100 described in relation with FIG. 1, has a phenomenon of relaxation after each application of a current across its terminals. According to an example, for a battery of this type outputting a voltage in the order of 3.6 V after applying a current, once the phenomenon of relaxation has appeared, its output voltage is less than 3.6 V.

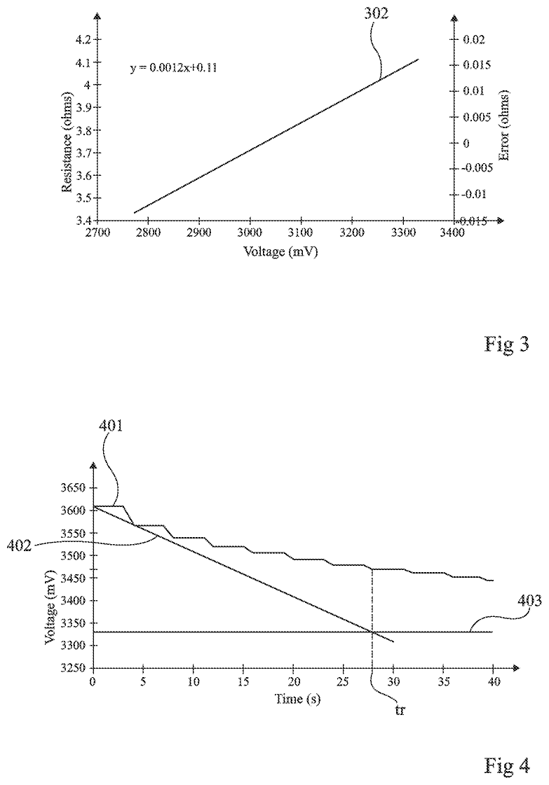

Referring now to FIG. 2, in a step 201 (Meas. R), a measurement of the resistance R of the battery is implemented. To this end, the battery is discharged with a relatively high current. According to an example, for a battery having a typical capacity in the order of 0.2 A/h or in the order of 1.6 A/h, a relatively high current is a current in the order of 800 mA. Measurements of the current and voltage delivered by the battery are performed all along this discharge. An example curve obtained during such a discharge is described in more detail in relation with FIG. 3.

A linear regression is performed from these measurements of voltage and current, and the value of the electric resistance, hereinafter called resistance, of the battery is derived from the slope coefficient of the line of the linear regression. More details are given in relation with FIG. 3.

In a step 202 (Meas. tr), a measurement of a time tr, and of a corresponding duration Dr, is implemented. To this end, a phenomenon of relaxation is induced in the battery to be tested. The following steps are implemented:
a step of discharge;
a step of partial charge of the battery up to reach an end-of-charge current of the battery; and
observing the phenomenon of relaxation and measuring the time tr.

According to an example, step 202 can be directly implemented after step 201, and the step of discharge of the battery in step 202 can thus be the step of discharge of step 201.

The step of charge of the battery can be implemented by supplying a constant current Itr and a constant voltage to the battery, also called settings CCCV. According to an example, the constant current Itr is comprised between 0.5 and 5 A, for example in the order of 1 A. According to an example, the constant voltage is comprised between 1 and 5 V, for example in the order of 3.6 V.

In addition, according to an embodiment, the end-of-charge current of the battery is defined as the current supplied to the battery at the end of its charging. In practice, one sets this current as equal to the typical capacity of the battery divided by ten hours.

Once the step of charging is completed, the current and the voltage applied to the battery are set to zero, and the voltage delivered by the battery is measured. As soon as the charging is stopped, the voltage delivered by the battery starts decreasing up to reach a level. An example curve obtained by this measurement is described in more detail in relation with FIG. 4. The level reached by the voltage corresponds to the voltage Vr, i.e., the voltage delivered by the battery as it is relaxed. According to an example, a measurement of the voltage Vr can be performed at this step.

In addition, in step 202, the time tr is measured. The time tr is the time when the tangent to the origin of the evolution over time of the voltage delivered by the battery, during the phenomenon of relaxation, reaches the value of the voltage Vr. In other words, the time tr is the time when this tangent intersects the horizontal line defined by the equation y=Vr. Determining the time tr is described in more detail in relation with FIG. 4.

It is deduced from the measurement of the time tr a measurement of a duration Dr corresponding to the difference between the time tr and a first time corresponding to the beginning of the phenomenon of relaxation.

Steps 201 and 202 are steps of characterising the battery. They both may be implemented as of the manufacturing of the battery. The values they allow calculating are theoretically independent from the aging of the battery.

In a step 203 (Meas. V(tr)), a measurement of the voltage V(tr) is implemented. The voltage V(tr) is the value of the voltage delivered by the battery when it is in use. In other words, as soon as a device using the battery starts operating, and starts being supplied by the battery, a measurement of the voltage delivered by the battery is performed at the end of the duration Dr, corresponding to the duration of the time tr. In other words, when the device starts operating, a first time is set, and as soon as the time tr is reached, the voltage delivered by the battery is measured, this voltage being the voltage V(tr). This step can be implemented at any use of the battery or of the electronic device including the battery.

The voltage V(tr) depends on the aging of the battery, this step thus outputs a value characteristic of the state of health of the battery.

In a step 204 (C), subsequent to the steps 201-203, determining the effective capacity of the battery is implemented using the values collected in steps 201-203. More particularly, Equation 1 previously defined is used to calculate the value of the effective capacity Ceff.

In a step 205 (SOH), subsequent to the step 204, determining the aging is implemented using the value of the effective capacity acquired in step 204. More particularly, the equation Math 2 previously defined is used to calculate the value of the aging.

Thus, the implementation mode of the method of measurement of the battery effective capacity comprises the steps 201 to 204, and the implementation mode of the method of measurement of the battery aging comprises the steps 201 to 205.

One advantage of these embodiments lays in it is easy to use. Further, it can be implemented by an embedded device associated with a battery, without requiring a high energy consumption. Indeed, the charging performed in step 202 is implemented only up to reach the end-of-charge current of the battery, and not the typical capacity of the battery. According to an example, such a charging can be any charging of the battery implemented during its use. In other words, step 202 can take advantage of a charging of the battery in order to be implemented.

FIG. 3 is a graph illustrating a curve 301 obtained during the step of measurement 201 described in relation with FIG. 2.

The curve 301 illustrates a linear regression of the value of the voltage delivered by the battery as a function of the value of the current delivered by this battery during the discharging implemented in step 201. According to an example, to obtain the curve 301, a circuit, such as a processor, a microprocessor, a controller, or a microcontroller, performs measurements of current and voltage. According to an example, the curve 301 is obtained with a gauge of the Gas Gauge type allowing a single battery cell to be monitored. These measurements may be synchronously or non-synchronously performed. According to a practical example, the values of the current are collected every 500 ms and the values of the voltage are collected every 4 s.

The value of the electrical resistance of the battery is obtained by determining the slope coefficient of the line 301 and using, Ohm's Law.

FIG. 4 is a graph illustrating curves 401-403 obtained during the step of measurement 203 described in relation with FIG. 2.

The curve 401 represents the evolution over time of the voltage delivered by the battery during the phenomenon of relaxation induced during the step 202. According to an example, the measurements of the voltage value are measured every 1 to 5 s, e.g., every 3 s.

The curve 402, or line 402, is the tangent to the origin of the curve 401, i.e., the tangent to the point of the curve 401 having o as abscissa.

The curve 403, or line 403, is a horizontal line having as ordinate the voltage Vr delivered by the battery as it is relaxed.

As previously described, the time tr is defined as being the abscissa of the intersecting point between the lines 402 and 403.

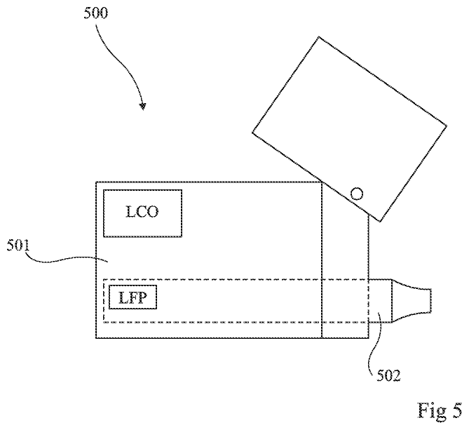

FIG. 5 illustrates a practical example of application such methods. More particularly, FIG. 5 illustrates an electronic cigarette 500.

The electronic cigarette 500 is constituted of a case 501 in which is inserted a cigarette holder 502.

The case 501 comprises a battery having a great storage capability, such as for example a Lithium-Ion battery of Lithium-Cobalt-Oxide type. The case 501 assumes as a function to serve as a wireless charger of the cigarette holder 502. The case may further comprise a display panel, for example such as a set of light emitting diodes.

The cigarette holder 502 is suitable to comprise and to be power supplied by a battery of the type of the battery 100 described in relation with FIG. 1. The cigarette holder 502 rather uses a battery of this type for safety reasons. Indeed, the batteries of Lithium-Ferro-Phosphate type have a phenomenon of technical runaway less severe than the other batteries of Lithium-ion type. In addition, the batteries of Lithium-Ferro-Phosphate type have a charging time shorter than the other batteries. This shorter charging time is due to a higher capacity of current sink of a Lithium-Ferro-Phosphate battery, such a battery can be charged up to five times its typical capacity without early aging.

The cigarette holder 502 may further comprise an electronic module associated with its battery. This module can be suitable to implement the implementation modes of the measurement methods described in relation with FIG. 2. According to an example, this module may be a processor, a microprocessor, a controller, or a microcontroller. According to another example, this module may be a gauge of the Gas Gauge.

Various embodiments and variants have been described. Those skilled in the art will understand that certain features of these embodiments can be combined and other variants will readily occur to those skilled in the art. In particular, other electronic devices are suitable to implement the implementation modes of the methods described in relation with FIG. 2.

Finally, the practical implementation of the embodiments and variants described herein is within the capabilities of those skilled in the art based on the functional description provided hereinabove.

What is claimed is:

1. A method of measuring an effective capacity of a battery, the method comprising:
performing a first measurement during a phenomenon of relaxation of the battery, the first measurement measuring a first voltage delivered by the battery when in use from a duration,
wherein the duration is the difference between a first initial time and a second time that is defined as the time when a first line reaches a second voltage delivered by the battery when the battery is relaxed, the first line being tangent to the origin of a curve corresponding to the evolution over time of a voltage delivered by the battery during the phenomenon of relaxation.

2. The method according to claim 1, wherein the phenomenon of relaxation of the battery is obtained by performing a partial charge of the battery until the battery requires an end-of-charge current, the phenomenon of relaxation appearing when the partial charge is interrupted.

3. The method according to claim 2, wherein the partial charge is performed at constant current and at constant voltage.

4. The method according to claim 2, wherein the value of the end-of-charge current is defined as being equal to the typical capacity of the battery divided by 10 hours.

5. The method according to claim 3, wherein the effective capacity is given by the following formula:
$$Ceff = Ctyp - R ( Vr - V ( tr ) )$$
where:
Ceff is the effective capacity;
Ctyp represents the typical capacity of the battery;
R represents the resistance of the battery;
Vr represents the voltage delivered by the battery when the battery is relaxed; and
V(tr) represents the first voltage.

6. The method according to claim 1, further comprising performing a second measurement of a resistance of the battery.

7. The method according to claim 6, wherein performing the second measurement comprises performing a second discharge of the battery with a first current.

8. The method according to claim 7, wherein the first current is greater than 500 mA.

9. The method according to claim 8, wherein the phenomenon of relaxation of the battery is obtained by performing a partial charge of the battery until the battery requires an end-of-charge current, the phenomenon of relaxation appearing when the partial charge is interrupted, and wherein the first discharge is the second discharge.

10. The method according to claim 9, wherein the battery is a Lithium Ferro-Phosphate type battery.

11. The method according to claim 1, wherein the battery is a battery of an electronic cigarette.

12. A method for measuring the aging of a battery, the method comprising:
performing a first measurement during a phenomenon of relaxation of the battery, the first measurement measuring a first voltage delivered by the battery when in use from a duration; and
determining the aging of the battery as a function of the first measurement;
wherein the duration is the difference between a first initial time and a second time that is defined as the time when a first line reaches a second voltage delivered by the battery when the battery is relaxed, the first line being tangent to the origin of a curve corresponding to the evolution over time of a voltage delivered by the battery during the phenomenon of relaxation.

13. The method according to claim 12, wherein determining the aging of the battery comprises finding a ratio of the effective capacity of the battery to the typical capacity of the battery.

14. The method according to claim 12, wherein the battery is a battery of an electronic cigarette.

15. A method of measuring an effective capacity of a battery, the method comprising:
performing a first measurement during a phenomenon of relaxation of the battery, the first measurement measuring a first voltage delivered by the battery when in use from a duration; and
performing a second measurement of a resistance of the battery when performing a second discharge of the battery with a first current;
wherein the duration is the difference between a first initial time and a second time that is defined as the time when a first line reaches a second voltage delivered by the battery when the battery is relaxed, the first line being tangent to the origin of a curve corresponding to the evolution over time of a voltage delivered by the battery during the phenomenon of relaxation; and
wherein the phenomenon of relaxation of the battery is obtained by performing a partial charge of the battery until the battery requires an end-of-charge current, the phenomenon of relaxation appearing when the partial charge is interrupted.

16. The method according to claim 15, wherein the partial charge is performed at constant current and at constant voltage.

17. The method according to claim 15, wherein the value of the end-of-charge current is defined as being equal to the typical capacity of the battery divided by 10 hours.

18. The method according to claim 15, wherein the first current is greater than 500 mA.

19. The method according to claim 18, wherein the phenomenon of relaxation of the battery is obtained by performing the partial charge of the battery until the battery requires the end-of-charge current, the phenomenon of relaxation appearing when the partial charge is interrupted, and wherein the first discharge is the second discharge.

20. The method according to claim 19, wherein the battery is a Lithium Ferro-Phosphate type battery.
